(19) United States
(12) Patent Application Publication
(10) Pub. No.: US 2007/0297028 A1
(43) Pub. Date: Dec. 27, 2007

(54) System and device for monitoring a computing device

(76) Inventors: Thomas Wulff, North Patchogue, NY (US); Thomas Conticello, St. James, NY (US)

Correspondence Address: FAY KAPLUN & MARCIN, LLP, 15O BROADWAY, SUITE 702, NEW YORK, NY, 10038, US

(21) Appl. No.: 11/471,949

(22) Filed: Jun. 21, 2006

(51) Int. Cl. G03F 3/08

(52) U.S. Cl. 358/520

(57) ABSTRACT

Described is a system and device for monitoring a computing device. The system comprises a mobile host computing device and a portable peripheral device detachably coupled to the host device. The peripheral device includes a microprocessor and a sensor. When the peripheral device is coupled to the host device, the sensors detect changes of at least one of spatial orientation and motion of the host device to generate data. The microprocessor compares the data to predetermined calibration data to detect an occurrence of an event.

### FIELD OF THE INVENTION

The present invention relates generally to systems and devices for monitoring a computing device.

### BACKGROUND

Businesses and individuals today rely on mobile computing products/arrangements (“MCPs”, e.g., bar code readers, RFID readers, PDAs, laptops, mobile phones, digital cameras, mobile optical readers, tablets, digital media players) in a multitude of situations ranging from basic everyday tasks to highly specialized procedures. As the virtues and benefits of utilizing MCPs continue to be realized across increasingly diverse industries, the features and capabilities of these products are expanding at a correspondingly rapid pace. For the businesses and individuals to purchase new MCPs for each updated feature/capability would be economically unfeasible. Thus, the updated feature/capability must be provided in a manner which is usable by the previously purchased MCPs.

### SUMMARY OF THE INVENTION

The present invention relates to a system and device for monitoring a computing device. The system comprises a mobile host computing device and a portable peripheral device detachably coupled to the host device. The peripheral device includes a microprocessor and a sensor. When the peripheral device is coupled to the host device, the sensors detect changes of at least one of spatial orientation and motion of the host device to generate data. The microprocessor compares the data to predetermined calibration data to detect an occurrence of an event.

### DESCRIPTION OF THE DRAWINGS

FIG. 1 shows an exemplary embodiment of a system for monitoring a computing device according to the present invention.

FIG. 2 shows an exemplary embodiment of a method for monitoring a computer device according to the present invention.

### DETAILED DESCRIPTION

The present invention may be further understood with reference to the following description and the appended drawings, wherein like elements are referred to with the same reference numerals. The present invention describes a system and device for monitoring a computing device. While the exemplary embodiments of the present invention will be described with reference to a mobile computing product/arrangement (“MCP”), those of skill in the art will understand that the systems and devices described herein may be implemented by any host electronic device for which it may be useful to detect directional orientation and motion thereof. For example, when installing/mounting a stationary device, it may be useful to analyze the directional orientation of the device and determine how operation would be impacted thereby.

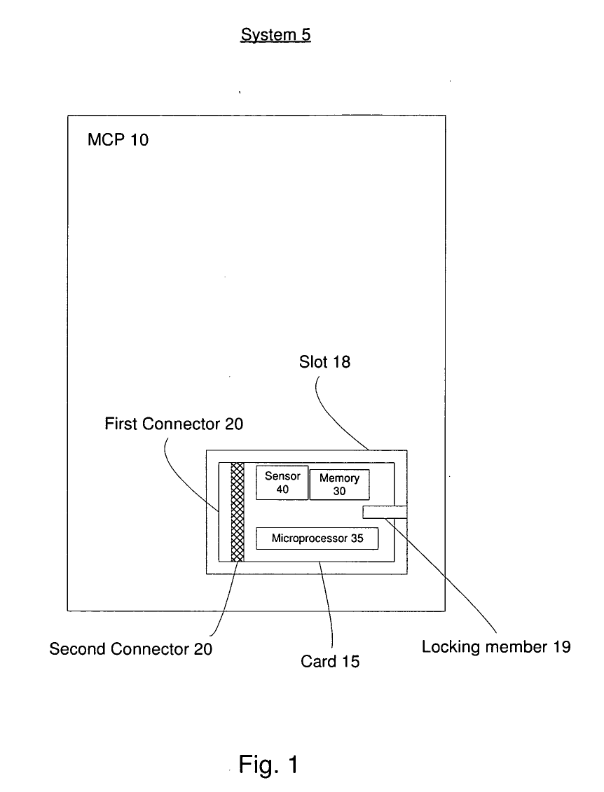

FIG. 1 shows an exemplary embodiment of a system 5 according to the present invention. The system 5 includes a host device (e.g., an MCP 10) which may be any type of computer or processor-based mobile device including, but not limited to, a laser/imager-based scanner, an RFID reader, a mobile phone, a PDA, a tablet, a digital camera, a laptop and a tablet. Since the MCP 10 is portable, it is capable of connecting to a wireless network and is sufficiently small to be easily carried. The MCP 10 may be designed for a specific purpose, e.g., scanning bar codes, or may be handheld device with various purposes to which various functionalities may be added by installing/downloading software and/or interfacing with a portable peripheral device providing additional functionality to the MCP 10, as will be described below.

In the exemplary embodiment, the peripheral device is a removable card 15 detachably coupleable to the MCP 10 which may include a slot 18 or sleeve for receiving the card 15. For example, the card 15 may be an SD card, a micro/mini SD card, a memory stick, a SIM card, a CF card, a PCMCIA card, etc. While the exemplary embodiment describes the peripheral device as the card 15, those of skill in the art will understand that the peripheral device may be any computing device which may be physically coupled to the MCP 10 and exchange data therewith via a hard port (e.g., serial connector, USB port) or a soft port (e.g., Bluetooth®, infrared). In any embodiment, the peripheral device should be in physical contact with the MCP 10 (e.g., mounted on or in, etc.) so that any movement, rotation, etc. of the MCP 10 results in similar movement of the peripheral device. This motion is detected by the card 15, as described below.

The slot 18 on the MCP 10 includes a first electrical connector 20 for electrically coupling to a second electrical connector 25 on the card 15. In other exemplary embodiments, an interface between the MCP 10 and the card 15 may be a serial peripheral interface (SPI), a wireless connection, an SD input/output (SDIO), etc. The slot 18 may further include a locking member 19 which ensures that the connectors 20, 25 remain electrically coupled and that the card 15 remains within the slot 18. The locking member 19 may be, for example, a latch or an overlay covering the slot 18.

The card 15 includes the second connector 25, a memory 30, a microprocessor 35 and one or more sensors 40. The microprocessor 35 may be a central processing unit that controls operation of the sensors 40 and executes instructions on measurements taken thereby. The measurements may be stored as data in the memory 30 and/or transmitted to a component (e.g., memory, processor, etc.) of the MCP 10 via the electrical coupling between the second connector 25 and the first connector 20. The memory 30 may be temporary (e.g., RAM, EEPROM, etc.), permanent (e.g., ROM) or a combination thereof.

The sensors 40 may be any type of measurement device capable of detecting and measuring spatial orientation and motion, and may be based on, for example, a G-shock sensor, a switch, an accelerometer, a strain gauge, a piezoelectric, micro-electromechanical (MEMS) sensors, or any combination thereof. The spatial orientation may include any angular movement relative to at least one axis in a three-dimensional reference frame. The motion may include, for example, a velocity and/or acceleration value, an angular velocity and/or acceleration value. Although, the sensors 40 may be of any size, the sensors 40 are preferably small enough so that they may be included on any standard size card without adding substantial weight thereto or increasing space occupied thereby. Because the MCP 10 is powered by a battery, the sensors 40 may also have a low power consumption rate. In other exemplary embodiments, the sensors 40 are rugged and capable of withstanding abusive environments in which the MCP 10 is used.

In the exemplary embodiment, the card 15 utilizes a single sensor 40 for detecting changes in the spatial orientation and motion of the card 15. An interface between the card 15 and the MCP 10 may be time-shared so that data throughput thereover may be conducted on two channels, e.g., between the memory 30 and the MCP 10 and the between the microprocessor 35 and the MCP 10. Data transfer over the interface may be in real-time or batched. Also, the card 15 may be serialized to the MCP 10 when serial numbers of the card 15 and the MCP 10 are exchanged. Thus, the spatial orientation and motion data may be authenticated as coming from a particular MCP. This ensures that the data on the card 15 reflects movement/use (e.g., drop data) of the particular MCP.

The sensors 40 detect changes in the spatial orientation and motion of the card 15 and, as a result, generate data which may be used by the MCP 10 to determine its own spatial orientation and motion. That is, the physical coupling of the MCP 10 and the card 15 ensures that both experience the same movement simultaneously. In the exemplary embodiment, the data is provided to the microprocessor 35 which compares the data to calibration data stored on the memory 30. The calibration data includes threshold ranges indicative of one or more predetermined events. For example, the calibration data may be a prerecorded rotation of the card 15 on one or more axes, prerecorded accelerations, etc.

When the data is outside the threshold range of the calibration data, the microprocessor 35 may send an event message to the processor of the MCP 10 indicating that the corresponding event has occurred. The MCP 10 may adjust its functionality based on the event message. For example, when the comparison of the data and the calibration data indicates that the card 15 has been rotated 180° on a particular axis, the microprocessor 35 may send a corresponding event message to the processor of the MCP 10 indicative of the rotation. The MCP 10 may use the event message to determine that a user of the MCP 10 is intending to, for example, use a mobile communications functionality, and activate a VoIP component.

While the exemplary embodiment describes the data being analyzed by the microprocessor 35 and the calibration data being stored in the memory 30 on the card 15, those of skill in the art will understand that the data generated by the sensors 40 may be transferred directly to the processor in the MCP 10 for processing and/or stored in memory on the MCP 10. The processor in the MCP 10 may process the data in a similar manner as described herein.

The microprocessor 35 may also append additional information to the data including sequential numbering of the events, time and date for each event, acceleration data, data corresponding to a status of the card 15 at the date/time of the event, environmental factors, a direction of movement, etc. In this manner, the microprocessor 35 may create an event history for the card 15. The event history may then be analyzed to further refine the calibration data and/or review use of the MCP 10 to determine whether it has been subjected to abuse (e.g., continuous drops).

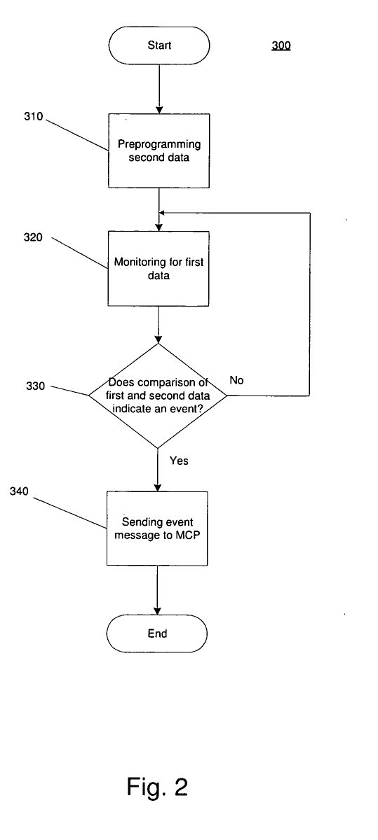

FIG. 2 shows an exemplary method 300 for monitoring the card 15. In the step 310, characteristics of the events are identified and programmed into the memory 30 as the calibration data. As described above, the calibration data may include threshold ranges for changes in spatial orientation and motion of the card 15 and/or the MCP 10. The ranges may be static, or customizable by a user.

In the step 320, the sensors 40 generate the data by detecting changes in the spatial orientation and/or motion of the card 15. The changes may be detected when, for example, the MCP 10 is rotated, turned, flipped, dropped, jerked, tugged, shaken, or being motionless for a specified duration. The sensors 40 may make no effort to differentiate between or prioritize directional orientation or motion values, returning all results to memory 30 and the microprocessor 35 for processing.

In the step 330, the microprocessor 35 compares the data to the calibration data in the memory 30 to determine whether the MCP 10 should be notified that an event has occurred. For example, when the sensors 40 detects that the card 15 came to an abrupt stop after being accelerated for a short period of time, the microprocessor 35 may conclude, based on the comparison of the data and the calibration data, that the card 15 has been dropped. From the magnitude and duration of acceleration and distance traveled, the microprocessor 35 may also determine whether the drop was forcibly induced (e.g., by an abusive user). Thus, the magnitude and duration of the acceleration may fall outside of the acceptable range in the second data.

Due to practical considerations (e.g., memory limitations and processing power) and because not all event occurrences may be significant, the reporting and recording of all movements, although possible, may in some instances be impractical. Reporting movements within acceptable limits (e.g., when the data is within the threshold ranges) to the MCP 10 may be superfluous. For example, small angular movements and accelerations may correspond to the same spatial orientation, i.e., the user may be re-orienting the MCP 10 to obtain a better scan of a bar code. These small movements, accelerations, etc. may be within the threshold range(s) and may not correspond to an event (e.g., rotating 180°).

When the data is within the threshold range, it may be stored in the memory 30 for future analysis. For example, if the user of the MCP 10 was attempting to adjust functionality of the MCP 10 based on a movement applied thereto, the stored data may be analyzed and used to adjust the threshold ranges, e.g., more or less sensitive to movement, rotation, etc.

When the comparison of the data and calibration data indicates that an event has occurred, the method 300 continues to step 350 where the microprocessor 35 outputs the event message to the processor of the MCP 10. In addition, the data may be stored in the memory 30 as an entry in the event history of the card 15. The event history may be readily accessible to any user of the card 15, or may be password protected and/or encrypted so that only authorized personnel (e.g., the network administrator or the manufacturer) may gain access. The MCP 10, upon receipt of the event message, may adjust its functionality (e.g., execute a predetermined procedure). For example, when the event message is indicative of a clockwise rotation, the MCP 10 may scroll forward through images on its display. The microprocessor 35 may include additional data in the event message including, for example, a precautionary warning to a user of the MCP 10.

In another exemplary embodiment, the MCP 10 may use the event message and/or the data and the calibration data to update a device event history. Based on the device event history, the MCP 10 may execute self-diagnostic and/or corrective procedures to, for example, refine the second data, cure defects resulting from abuse, request maintenance and/or replacement, etc. In instances where the MCP 10 processes the event messages and/or first and second data and determines that it is being abused, the user may intercede to minimize the abusive treatment, thereby reducing service to and/or replacement of the MCP 10.

The data generated by the sensors 40 in the card 15 may be used in a variety of settings including, for example, power management, gesture input, compensating for undesired motion, display orientation, and security. The data may be used to determine whether the MCP 10 has been dropped or suffered any other abuse. Similarly, when the data indicates that a drop has been initiated (e.g., when the MCP 10 leaves the user's hand), the MCP 10 may initiate a system shut-down to prevent loss/corruption of data in the case of a power supply termination after the drop/impact.

The data may also be used to selectively power components of the MCP 10. For example, when the MCP 10 is a vehicle radio computer, the data may be used to determine when the vehicle is in motion and power down a display screen, preventing distraction of a driver. The data may also be used to selectively power wireless communications functionalities of the MCP 10. For example, when the data indicates that the MCP 10 is held like a telephone handset, the MCP 10 may utilize a near-field communications mode. When the MCP 10 is held like a walkie-talkie, the MCP 10 may switch to a far-field communications mode (e.g., speaker phone).

The power management properties of MCPs have been a primary focus of product design engineers. Due to their limited size and weight and their mobile nature, MCPs usually have limited power supplies (e.g., rechargeable or disposable battery packs). Developing MCPs that operate for long periods of time, without sacrificing mobility, is an ongoing design challenge. Designing a robust power management system that optimizes and conserves power is a critical element in addressing this challenge.

With knowledge of its spatial orientation from the event message, the MCP 10 may self-regulate its power management systems by turning on and off various systems when appropriate. For example, the MCP 10 may have a display and backlight that use a large amount of the available power supply. In processing the event message, the MCP 10 may determine that it is in a user-viewable orientation and, as such, powers the display and backlight. When the MCP 10 determines that it is in a non-viewable orientation, the display and backlight may shut off to save power.

The MCP 10 may also use the event message to switch into a power-save mode. Conventional power management systems typically shut down the MCP 10 or switch it into the power-save mode after a preset time period of non-use. The event message may indicate a lack of motion and/or a predefined orientation (e.g., display down) which the MCP 10 uses as an additional trigger to switch into the power-save mode.

Motion and/or orientation of the MCP 10 may also be used as a gestural input for interfacing with the MCP 10. Use of the features of the MCP 10 typically involves navigation of menus, onscreen buttons, etc. The event message allows the MCP 10 to recognize and react to various motions or user gestures. These motions or gestures may trigger the MCP 10 to perform various functions that would otherwise need to be actuated manually. For example, if the display of the MCP 10 is in a document viewing mode, a roll of the user's wrist detected by the sensors 40 may be interpreted by the MCP 10 to scroll to the next page of the document. In another example, when the MCP 10 includes a data capture arrangement (e.g., an imager, scanner, camera), a motion corresponding to a pre-recorded gesture may trigger the MCP 10 to turn on the data capture functionality.

Still another advantage of the present invention is the ability to compensate for undesirable motion. Minor movements may adversely affect applications that require the MCP 10 to be relatively stationary. For example, the MCP 10 may utilize an imager which may produce blurred or out of focus images if the MCP 10 is moving during image capture. When the image capture functionality is active, the MCP 10 may use the event message to identify a non-acceptable operating situation and automatically compensate for the motion during the image capture by activating conventional image stabilization software.

The orientation sensing capability of the present invention may also conveniently allow the MCP 10 to adjust the display orientation. That is, the display typically formats data in a landscape or portrait mode. The present invention allows the MCP 10 to adjust the display orientation automatically based the event message, switching the display data format between the landscape and portrait modes.

In a further exemplary application of the present invention, the MCP 10 may utilize the event message for purposes of security. Because the MCP 10 is portable, it may be easily misplaced or stolen. When the event message indicates a lack of motion or non-use (e.g., during recharge, overnight storage), the MCP 10 may enter a secure mode. The MCP 10 may require a password, biometric, etc. for returning to operational mode.

It will be apparent to those skilled in the art that various modifications may be made in the present invention, without departing from the spirit or scope of the invention. Thus, it is intended that the present invention cover the modifications and variations of this invention provided they come within the scope of the appended claims and their equivalents.

What is claimed is:

1. A system, comprising:
a mobile host computing device; and
a portable peripheral device detachably coupled to the host device, the peripheral device including a microprocessor and a sensor,
wherein, when the peripheral device is coupled to the host device, the sensor detects changes of at least one of spatial orientation and motion of the host device to generate data, and
wherein, the microprocessor compares the data to predetermined calibration data to detect an occurrence of an event.

2. The system according to claim 1, wherein, upon detection of the event, the microprocessor generates and transmits an event message to the host device, and the host device executes a predetermined procedure as a function of the event message.

3. The system according to claim 1, wherein the peripheral device is one of a SIM card, a SD card, a CF card, a PCMCIA card, a mini SD card, a micro SD card, a memory stick, and a USB device.

4. The system according to claim 1, wherein the host device includes at least one of a laser-based scanner, an imager-based scanner, an RFID reader, a mobile phone, a PDA, a tablet, a laptop, a digital camera and a portable media player.

5. The system according to claim 1, wherein the host device includes one of a slot and a sleeve for receiving the peripheral device.

6. The system according to claim 1, wherein the sensor is one of a G-shock sensor, a switch, an accelerometer, a strain gauge, a piezoelectric and a micro-electromechanical (MEMS) sensor.

7. The system according to claim 1, wherein the calibration data includes predetermined threshold ranges for the at least one of spatial orientation and motion of the host device.

8. The system according to claim 7, wherein, when the data is outside of the predetermined threshold ranges, the microprocessor generates an event message.

9. The system according to claim 1, wherein the predetermined action is an adjustment in operation of a component of the host device.

10. A portable peripheral device for detachably coupling to a mobile host computing device, comprising:
a sensor detecting, when the peripheral device is coupled to the host device, changes of at least one of spatial orientation and motion of the host device to generate data; and
a microprocessor compares the data to predetermined calibration data to detect an occurrence of an event.

11. The device according to claim 10, further comprising:
a communications arrangement transmitting, upon detection of the event, an event message to the host device.

12. The device according to claim 10, wherein the sensor is one of a G-shock sensor, a switch, an accelerometer, a strain gauge, a piezoelectric and a micro-electromechanical (MEMS) sensor.

13. The device according to claim 10, further comprising:
a memory storing the data and the calibration data, the memory including at least one of a temporary memory and a permanent memory.

14. The device according to claim 10, wherein the calibration data includes predetermined threshold ranges for the at least one of spatial orientation and motion of the host device.

15. The device according to claim 14, wherein, when the data is outside of the predetermined threshold ranges, the microprocessor generates an event message.

16. The device according to claim 11, wherein the communications arrangement is one of a serial connector, a USB connector, a Bluetooth radio, a serial peripheral interface, an SD input/output and an infrared generator.

17. The device according to claim 10, wherein the host device includes at least one of a laser-based scanner, an imager-based scanner, an RFID reader, a mobile phone, a PDA, a tablet, a laptop, a digital camera and a portable media player.

18. A method, comprising:
detecting with a sensor of a portable peripheral device, changes of at least one of spatial orientation and motion of a mobile host computing device to generate data, the peripheral device being detachably coupled to the host device; and
comparing the data to predetermined calibration data to detect an occurrence of an event.

19. The method according to claim 18, further comprising:
upon detection of the event, transmitting an event message to a host processor on a host device.

20. The method according to claim 18, further comprising:
recording a plurality of orientations and motions of the host device using the sensors; and
generating the calibration data as a function of the recorded orientations and motions.

21. A portable peripheral device, comprising:
sensing means for sensing at least one of spatial orientation and motion of a host device to generate data, the portable peripheral device being coupled to the host device;
a data storage means for storing calibration data and the data; and
a processing means for comparing the data to predetermined calibration data to detect an occurrence of an event.
